(19) United States
(12) Patent Application Publication
(10) Pub. No.: US 2025/0070044 A1
(43) Pub. Date: Feb. 27, 2025

(54) Vertical Semiconductor Devices with Deep Well Region for Radiation Hardening

(71) Applicant: SCDevice LLC, Portland, OR (US)

(72) Inventors: David Lee Snyder, Beaverton, OR (US); Sudarsan Uppili, Portland, OR (US); Scott Joseph Alberhasky, Hillsboro, OR (US)

(21) Appl. No.: 18/813,547

(22) Filed: Aug. 23, 2024

Related U.S. Application Data
(60) Provisional application No. 63/534,116, filed on Aug. 23, 2023.

(51) Int. Cl. H01L 23/552; H01L 29/06; H01L 29/66; H01L 29/78

(52) U.S. Cl. CPC H01L 23/552; H01L 29/0684; H01L 29/66727; H01L 29/7802

(57) ABSTRACT

Vertical semiconductor devices with deep wells and associated fabrication methods are disclosed herein. A disclosed process for forming a semiconductor device includes forming, on a drift region having a first conductivity type, a deep well region for the semiconductor device. The deep well region can be formed by an implant. The deep well region has a second conductivity type. The deep well region of the second conductivity type leaves a portion of the surface of the drift region exposed. The process also includes epitaxially forming a semiconductor region that extends from the surface of the drift region to above the deep well region for the semiconductor device. The semiconductor region can be used as at least a part of the main operational current path of the semiconductor device when the semiconductor device is finished and is devoid of implant damage from the implant.

### CROSS REFERENCE TO RELATED APPLICATIONS

This application claims the benefit of U.S. Provisional Patent Application No. 63/534,116, filed Aug. 23, 2023, which is incorporated by reference herein in its entirety for all purposes.

### BACKGROUND

Semiconductor devices can include deep regions which are designed to impact the performance of the device in various ways. They are referred to as deep regions because they are relatively farther away from the top surface of the semiconductor devices as compared to the other features of the semiconductor devices. Deep regions are also often referred to as buried regions or buried layers because there are other regions or layers between them and the surface of the semiconductor device. Deep well regions are specialized areas within a semiconductor device which have a significantly higher concentration of charge carriers than the surrounding material. This doping creates a deep potential well, allowing the region to act as a barrier or isolation layer for specific device functions.

Vertical semiconductor devices are a class of electronic components that are characterized by their unique vertical architecture, in which the operational current flow of the device includes a path that is substantially normal to the main surface of the semiconductor device. This contrasts with traditional lateral devices in which the operational current flows substantially parallel to the main surface of the semiconductor device. These vertically oriented structures enable superior performance in terms of power handling, heat dissipation, and integration density. Examples of vertical semiconductor devices include vertical field-effect transistors (FETs) and vertical junction barrier Schottky (JBS) diodes.

### SUMMARY

Vertical semiconductor devices with deep wells and associated fabrication methods are disclosed herein. The vertical semiconductors can be vertical field effect transistors (FETs). The vertical semiconductor devices can be metal insulator semiconductor field effect transistors (MISFETs) such as vertical MISFETs. The vertical semiconductor device can be vertical diodes. The diodes can be junction barrier Schottky (JBS) diodes such as vertical JBS diodes.

In specific embodiments of the invention, the semiconductor devices are designed for radiation-environment applications and are radiation hardened devices. In specific embodiments, the semiconductor devices exhibit single event burnout (SEB) resistances of greater than 1200 volts. In specific embodiments of the invention, the deep wells disclosed herein provide radiation hardening to the semiconductor devices to which they are a part.

The semiconductor devices disclosed herein can be formed in silicon carbide or silicon substrates. The semiconductor devices can include regions of a first conductivity type and regions of a second, opposite, conductivity type. The regions of different conductivity can be formed by doping the substrate materials with various dopants such as aluminum and nitrogen for silicon carbide, and boron, phosphorus, and arsenic for silicon. Example levels of conductivity types provided with reference to a well dopant region formed in a drift region (i.e., well doping, NW, or PW), a heavily doped region (i.e., N+ or P+ region) formed in a drift region, and a drift region itself include: a P+ region from 5×10¹⁸ to 1×10²¹ cm⁻³, a p-well region (well doping or PW) from 1×10¹⁷ to 5×10¹⁸ cm⁻³, and an N-drift region from 5×10¹⁴ to 5×10¹⁶ cm⁻³. As used herein, doping concentrations refer to the number of impurity molecular entities per cubic centimeter implanted or dispersed into a semiconductor region.

In specific embodiments of the invention, the deep wells disclosed herein can have peak doping concentrations of between 1×10¹⁹ to 1×10²¹ impurity molecular entities per cubic centimeter while still being able to form a functional MISFET or JBS diode above the deep well region because, using the approaches disclosed herein, the channel, or other main current path region of the semiconductor device, is formed after the deep well region has been implanted through a high energy implant. In accordance with prior art approaches, deep well regions formed by implanting through a channel, or other main current path region of a semiconductor device, result in implant damage through the main current path region. Prior art approaches were limited in terms of the maximum concentration of the deep well regions due to the potential for implant damage to produce unsatisfactory or dysfunctional semiconductor devices having low mobility or purely ineffective channels. This is a disadvantageous restriction because higher deep well concentrations can serve to protect the semiconductor device in high radiation environments.

Specific embodiments disclosed herein enable the creation of a heavily doped deep well region having a peak doping concentration that exceeds 1×10¹⁹ cm⁻³ and that can be as high as 1×10²¹ cm⁻³. Specific embodiments disclosed herein enable this level of doping while having a minimal impact on alternative aspects of the semiconductor device design. For example, using specific embodiments of the inventions disclosed herein, the deep well region can exhibit the above-mentioned doping concentration while being formed farther from the main surface of the semiconductor device than would otherwise be available. Added depth is available because using traditional approaches to form high doping concentrations deep into semiconductor material can inadvertently damage the material through which the implant is conducted. Furthermore, in specific embodiments in which a channel or gate will be formed above the deep well region, using the approaches disclosed herein, the doping profile of the deep well region and the doping of the channel or gate region of the device can be entirely separated because they are conducted into different portions of the semiconductor device without one implant having to pass through the other.

The above-mentioned benefits are provided by specific embodiments of the inventions disclosed herein because they avoid the need to conduct heavy implants from the main surface of the semiconductor device which can lead to defects that affect the performance and reliability of the device and that result in uncontrolled channel doping for devices in which achieving a targeted channel doping impacts the figures of merit for the device. As used herein the term “main surface” of the semiconductor device should be interpreted according to its plain and ordinary meaning as the top surface of a semiconductor device above which the contacts to the semiconductor material, wiring for the semiconductor device, and isolation layers for the semiconductor device are formed.

Deep heavily doped regions can exhibit certain benefits for the semiconductor device of which they form a part. For example, the deep region can serve as a shield region to increase the radiation hardening of the semiconductor device. In a reverse biased high voltage device exposed to heavy ion radiation, the presence of a heavily doped deep region can remove holes created by the radiation and reduce the formation of high electric fields and mitigate temperature rise in the region of the ion strike in the semiconductor. In a MISFET device, the heavily doped deep well region can decrease the electric field formed across the gate insulator increasing the FET's reliability by decreasing the potential for gate oxide rupture due to ion radiation. Reduction of the holes and electric fields in the path of the ion strike are important for designing devices that are resistant to heavy ion radiation. In a JBS diode, the heavily doped deep well region can serve as a bottom plate for the JBS diode which is beneficial for the same reasons as in the MISFET device in the event of an ion strike.

When subjected to heavy ion strike, commercial devices can go into catastrophic failure called single event burnout mode. However, specific embodiments of the invention disclosed herein form a device with a heavily doped deep well region that maintains a lattice temperature under 1000° K under ion bombardment. This in turn prevents the device from experiencing single event burnout. The heavily doped deep well region also reduces electric field from levels that could cause dielectric rupture to levels at which the gate oxide is regarded as having stable reliability. The heavily doped deep well region is effective in shunting the holes away from the ion strike. The heavily doped deep well region also supplies no electrons to feed the electron/hole filament formed by the heavy ion strike.

FIG. 1 shows simulation results for peak silicon carbide temperature for a silicon carbide MISFET device with a 600 volt drain to source voltage (VDS) and a liner energy transfer (LET) of 40 MeV-cm²/mg with and without a deep well region in accordance with this disclosure in plot 100. The time is shown in units of seconds and the temperature is shown in degrees Celsius. FIG. 1 also shows the peak e-field in the insulator of the MISFET for a device with and without a deep well region in accordance with this disclosure in plot 110. In the illustrated cases the deep well region is a P+ deep well region.

In specific embodiments of the invention disclosed herein, a deep well region is formed either through the deposition of a heavily doped in situ epitaxial layer followed by a masked etch, or through a masked implant process. Both techniques result in a discontinuity in the buried deep well region. The buried deep well is subsequently covered with an epitaxial cap layer. This portion of the epitaxial cap layer formed on top of the buried deep well region can serve as the region of the device in which a channel and gate are generated in specific semiconductor devices. Since the epitaxial cap layer is formed after the buried deep well is formed, and because the epitaxial cap layer can be implanted from the main surface without having to pass through the buried deep well, the doping of the two regions can be considered separately which adds significant flexibility to the design of the semiconductor device.

In specific embodiments of the invention, a method for forming a semiconductor device is provided. The method comprises forming, on a drift region having a first conductivity type, a deep well region for the semiconductor device. The deep well region has a second conductivity type. The deep well region of the second conductivity type leaves a surface of the drift region exposed. The method further comprises epitaxially forming a semiconductor region that extends from the surface of the drift region to above the deep well region for the semiconductor device. The epitaxial formation of the semiconductor region is conducted after the forming of the deep well region. The semiconductor region can be referred to as an epitaxial cap layer. In a finished device the epitaxial cap layer can form a portion of the deep well region. The same epitaxial cap layer can also form at least a portion of the main operational current path of the finished device.

### BRIEF DESCRIPTION OF THE DRAWINGS

The accompanying drawings illustrate various embodiments of systems, methods, and various other aspects of the disclosure. A person of ordinary skill in the art will appreciate that the illustrated element boundaries (e.g., boxes, groups of boxes, or other shapes) in the figures represent one example of the boundaries. It may be that in some examples one element may be designed as multiple elements or that multiple elements may be designed as one element. In some examples, an element shown as an internal component of one element may be implemented as an external component in another, and vice versa. Furthermore, elements may not be drawn to scale. Non-limiting and non-exhaustive descriptions are described with reference to the following drawings. The components in the figures are not necessarily to scale, emphasis instead being placed upon illustrating principles.

FIG. 1 provides two plots comparing the performance of a semiconductor device with a deep well in accordance with specific embodiments of the inventions disclosed herein and a semiconductor device without a deep well.

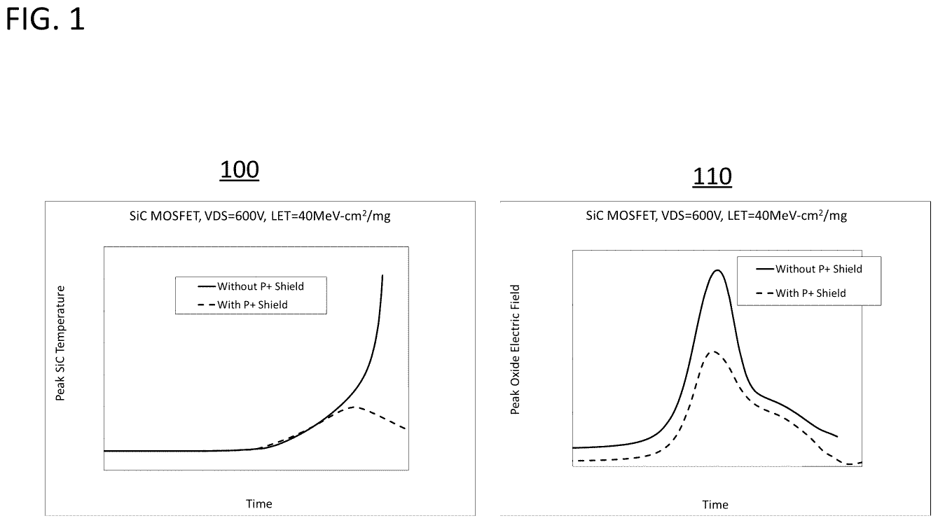

FIG. 2 illustrates a cross section of a MISFET semiconductor device having a deep well trench contact in accordance with specific embodiments of the inventions disclosed herein.

FIG. 3 illustrates a cross section of a MISFET semiconductor device in accordance with specific embodiments of the inventions disclosed herein.

FIG. 4 illustrates a flow chart for a set of methods for forming a SiC MISFET semiconductor device in accordance with specific embodiments of the inventions disclosed herein.

FIG. 5 illustrates a cross section of a semiconductor device in the process of being fabricated in accordance with a method illustrated by FIG. 4 having a drift region formed on a substrate in accordance with specific embodiments of the inventions disclosed herein.

FIG. 6 illustrates a cross section of a semiconductor device in the process of being fabricated in accordance with a method illustrated by FIG. 4 having an epitaxially formed deep well region formed on a drift region in accordance with specific embodiments of the inventions disclosed herein.

FIG. 7 illustrates a cross section of a semiconductor device in the process of being fabricated in accordance with a method illustrated by FIG. 4 having an epitaxially formed deep well region that has been subjected to a masked etch in accordance with specific embodiments of the inventions disclosed herein.

FIG. 8 illustrates a cross section of a semiconductor device in the process of being fabricated in accordance with a method illustrated by FIG. 4 having an epitaxially formed semiconductor region formed over the deep well region in accordance with specific embodiments of the inventions disclosed herein.

FIG. 9 illustrates a cross section of a semiconductor device in the process of being fabricated in accordance with a method illustrated by FIG. 4 having an epitaxially formed semiconductor region that has been implanted with two separate implants to form a second deep well region and a shallow well region in accordance with specific embodiments of the inventions disclosed herein.

FIG. 10 illustrates a cross section of a semiconductor device in the process of being fabricated in accordance with a method illustrated by FIG. 4 having a shallow well region that has been implanted to form a source contact in accordance with specific embodiments of the inventions disclosed herein.

FIG. 11 illustrates a cross section of a semiconductor device in the process of being fabricated in accordance with a method illustrated by FIG. 4 having a shallow well and a deep well that have been implanted to form a deep well contact in accordance with specific embodiments of the inventions disclosed herein.

FIG. 12 illustrates a cross section of a semiconductor device in the process of being fabricated in accordance with a method illustrated by FIG. 4 that has been annealed to activate the implanted dopants and that has been oxidized to form a gate insulator in accordance with specific embodiments of the inventions disclosed herein.

FIG. 13 illustrates a cross section of a semiconductor device in the process of being fabricated in accordance with a method illustrated by FIG. 4 that has a layer of polysilicon deposited on the gate insulator in accordance with specific embodiments of the inventions disclosed herein.

FIG. 14 illustrates a cross section of a semiconductor device in the process of being fabricated in accordance with a method illustrated by FIG. 4 that has a layer of polysilicon that has been etched to form a gate electrode in accordance with specific embodiments of the inventions disclosed herein.

FIG. 15 illustrates a cross section of a semiconductor device in the process of being fabricated in accordance with a method illustrated by FIG. 4 that has been etched to form a trench contact in accordance with specific embodiments of the inventions disclosed herein.

FIG. 16 illustrates a cross section of a semiconductor device in the process of being fabricated in accordance with a method illustrated by FIG. 4 that has been etched to expose a source contact in accordance with specific embodiments of the inventions disclosed herein.

FIG. 17 illustrates a cross section of a semiconductor device in the process of being fabricated in accordance with a method illustrated by FIG. 4 on which a layer of silicide has been formed to provide an ohmic contact to the source contact, deep well, and deep well contact in accordance with specific embodiments of the inventions disclosed herein.

FIG. 18 illustrates a cross section of a semiconductor device in the process of being fabricated in accordance with a method illustrated by FIG. 4 on which a layer of metal has been formed on the silicide in accordance with specific embodiments of the inventions disclosed herein.

FIG. 19 illustrates a flow chart for a set of methods for forming a SiC MISFET semiconductor device using a masked implant and anneal to form the deep well region in accordance with specific embodiments of the inventions disclosed herein.

FIG. 20 illustrates a cross section of a semiconductor device in the process of being fabricated in accordance with a method illustrated by FIG. 19 having a drift region formed on a substrate in accordance with specific embodiments of the inventions disclosed herein.

FIG. 21 illustrates a cross section of a semiconductor device in the process of being fabricated in accordance with a method illustrated by FIG. 19 having a mask implant formed deep well region formed on a drift region in accordance with specific embodiments of the inventions disclosed herein.

FIG. 22 illustrates a cross section of a semiconductor device in the process of being fabricated in accordance with a method illustrated by FIG. 19 having an epitaxially formed semiconductor region formed over the deep well region, which was formed using a masked implant, in accordance with specific embodiments of the inventions disclosed herein.

### DETAILED DESCRIPTION

Reference will now be made in detail to implementations and embodiments of various aspects and variations of systems and methods described herein. Although several exemplary variations of the systems and methods are described herein, other variations of the systems and methods may include aspects of the systems and methods described herein combined in any suitable manner having combinations of all or some of the aspects described.

Different systems and methods related to the field of semiconductor devices with deep wells in accordance with the summary above are disclosed in detail herein. The methods and systems disclosed in this section are nonlimiting embodiments of the invention, are provided for explanatory purposes only, and should not be used to constrict the full scope of the invention. It is to be understood that the disclosed embodiments may or may not overlap with each other. Thus, part of one embodiment, or specific embodiments thereof, may or may not fall within the ambit of another, or specific embodiments thereof, and vice versa. Different embodiments from different aspects may be combined or practiced separately. Many different combinations and sub-combinations of the representative embodiments shown within the broad framework of this invention, which may be apparent to those skilled in the art but not explicitly shown or described, should not be construed as precluded.

Devices are disclosed herein that can operate in high voltage and high-power applications in the absence of radiation. These devices can operate with an off-voltage up to 20,000 volts and with on currents in the range of 0.1 to 40 amperes. The devices can be formed on silicon carbide substrates, silicon substrates, or substrates of various other types of semiconductor material. The devices can be used in DC-DC converters, switched mode power supplies, and various other kinds of circuits and applications.

Devices are disclosed herein that are radiation tolerant. Such devices can operate in space electronic power conditions and high-altitude conditions. In certain space applications, the use of silicon carbide devices can increase payload integration and free up space for alternative components. The devices can be used as satellite power components and solar array high voltage blocking devices. In specific embodiments of the invention disclosed herein, radiation tolerant silicon carbide devices can exhibit useful performance for high power applications while experiencing a radiation bombardment with a linear energy transfer (LET) of up to 90 MeV-cm²/mg. The devices can exhibit a resistance to single event burnout (SEB) with off voltages up to 1,200 volts. As used herein, the term “linear energy transfer” is used to indicate the average amount of energy that is lost per unit path-length as a charged particle travels through a given material.

The disclosure includes a description of MISFET devices with heavily doped deep wells that are in accordance with this disclosure, JBS diodes with heavily doped deep wells in the form of bottom plate contacts that are in accordance with this disclosure, and methods of making these devices. The deep well processes described in this disclosure may be formed using an implanted process or an in situ epitaxial process for devices including, but not limited to, MISFET and JBS diodes.

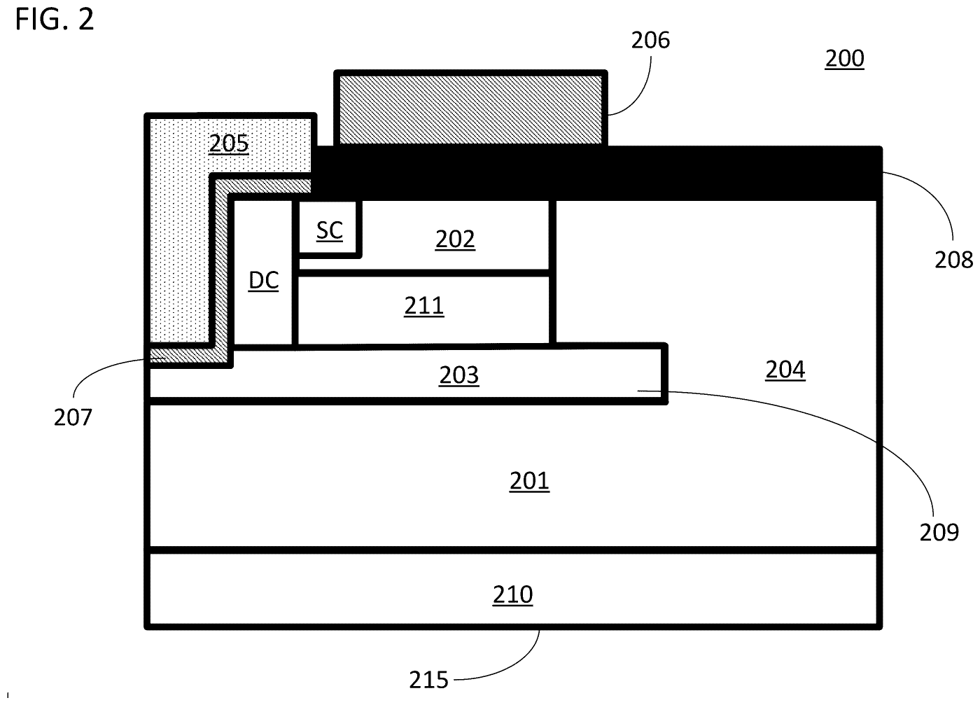

FIG. 2 is a cross section taken from device 200 (e.g., a vertical MISFET device) in accordance with specific embodiments of the invention disclosed herein. The cross section illustrates a single gate device and shows only the left half of the symmetric MISFET for brevity. The cross sections include a substrate 210 on which the MISFET device is formed. The substrate can be silicon carbide, silicon, or any other kind of semiconductor material. The devices can include regions of different conductivity types formed through the introduction of dopants. The regions can include regions of a first conductivity type and a second conductivity type. The first conductivity type could be n-type and the second conductivity type could be p-type or vice versa. For example, the devices could be formed in a silicon carbide substrate and include regions where the dopant for the p-type regions is aluminum and the dopant for the n-type regions is nitrogen.

The device in FIG. 2 includes various regions. The device includes a drift region 201 of a first conductivity type. The drift region can be formed through the epitaxial growth of a layer on a top surface of the substrate. The breakdown rating of the device depends on the doping concentration and thickness of the drift region. As a non-limiting example, the drift region could be an n-type region for a radiation tolerant device and be formed through epitaxial deposition of materials on the substrate and could have a peak doping concentration of between 1×10¹⁴ to 1×10¹⁶ cm⁻³.

The device in FIG. 2 includes a shallow well region 202 of a second conductivity type. In specific embodiments of the invention, the shallow well region can be a p-type region with a peak doping concentration of less than 1×10¹⁸ cm⁻³ and greater than 5×10¹⁶ cm⁻³.

The device in FIG. 2 also includes a deep well region 203 of the second conductivity type and located between the shallow well region 202 and the drift region 201. In specific embodiments of the invention, the deep well can be a p-type region with a peak doping concentration between 1×10¹⁷ and 1×10²¹ cm⁻³. In specific embodiments, the deep well of the device can include two deep well regions including deep well region 203 serving as a first deep well region and second deep well region 211. The doping concentration of second deep well region 211 can be less than the doping concentration of deep well region 203. In specific embodiments of the invention, the second deep well can be a p-type region with a peak doping concentration between 1×10¹⁷ and 1×10¹⁹ cm⁻³. The deep well can include a discontinuity in the doping concentrations at the border between the two deep well regions. In specific embodiments, the second deep well region is not present and the shallow well is in direct contact with the first deep well region.

The device in FIG. 2 also includes a junction field effect region 204 in contact with shallow well region 202, drift region 201, and deep well region 203, and having a JFET doping concentration of the first conductivity type. In specific embodiments of the invention, the JFET transistor region of the device can have a peak doping concentration of less than 5×10¹⁷ cm⁻³ and greater than 5×10¹⁴ cm⁻³.

The device in FIG. 2 also includes contact regions. The device includes a source contact region (SC) of the first conductivity type in contact with the shallow well regions, and a deep well contact region (DC) of the second conductivity type in contact with the deep well region 203, the shallow well region 202, and the source contact region SC. In specific embodiments of the invention, deep well contact region DC is also in contact with shallow well region 202 in a different cross section of the device. Source contact region SC can be a region of high doping concentration and be used to ohmically couple the conductive channel of the transistor to an external contact. Deep well contact region DC can also be a region of high doping concentration and be used to ohmically couple deep well region 203 and shallow well region 202 with an external contact for purposes of biasing deep well region 203 and shallow well 202 regions.

FIG. 2 also indicates the terminals of the device. As illustrated, a source terminal 205 is coupled to deep well region 203, deep well contact DC, and source contact SC by a layer of silicide 207. The cross section also illustrates a gate terminal 206 of the transistor being separated from shallow well region 202 by an insulator layer 208. The cross section also indicates where a drain terminal 215 would be formed on the back side of substrate 210. Drain terminal 215 is below deep well region 203 and source terminal 205 is at least partially above deep well region 203. The term “at least partially” is used here because source terminal 205 is formed in a trench which extends down to the level of deep well region 203 to assure adequate bias of the source region so source terminal 205 is not entirely above deep well region 203.

As illustrated, deep well region 211 can be separated from source contact region SC by a portion of shallow well region 202. Using the approaches disclosed herein, the doping profile of the deep well can be set without reference to the thickness of shallow well region 202 such that shallow well region 202 can be made thicker and source contact SC can remain separated from deep well region 211.

As illustrated, deep well region 203 can include a notch 209 which is formed by the discontinuity mentioned above, the formation of which is described with reference to the process flows below. The notch 209 shows how the width of deep well region 203 and the relative widths of shallow well region 202 and source contact SC can be independent of the doping of deep well region 203 as notch 209 is formed separately from deep well region 211 and prior to the formation of the regions above notch 209. The illustrated deep well region 203 has both a top and side surface in contact with junction field effect region 204. Due to notch 209, deep well region 203 covers the gate formed by gate terminal 206 (e.g., a gate electrode) from a bottom-up perspective. In this manner, the notch 209 serves to protect the device by reducing the electric field at the surface during ion bombardment.

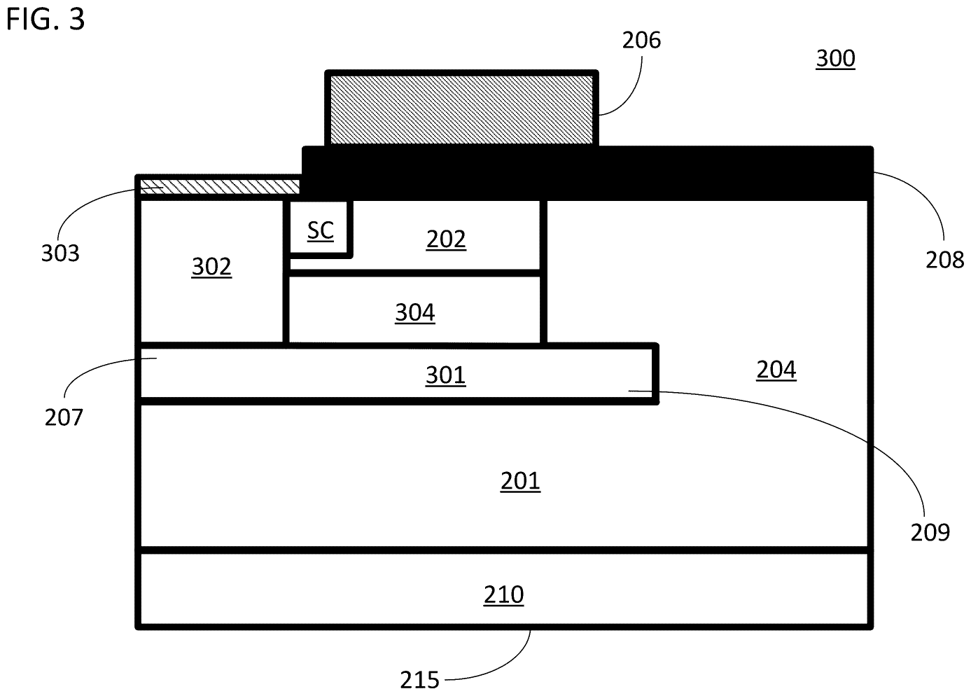

FIG. 3 illustrates a device 300 (e.g., a MISFET) that is similar to that of FIG. 2 except that it does not include a trench contact to the deep well and instead includes a planar contact. In the illustrated case, deep well region 301 is biased by a larger deep well contact 302 that can have similar doping to deep well contact DC of FIG. 2. The device also has a silicide region 303 that does not extend down into a trench because it is not deposited after a trench has been formed as in the case of device 200. Device 300 also includes a second deep well region 304 with similar characteristics to that of second deep well region 211. While the device in FIG. 3 may not provide as low of an impedance path to deep well region 301 as the device in FIG. 2 does for its deep well region, the device can be made with fewer processing steps.

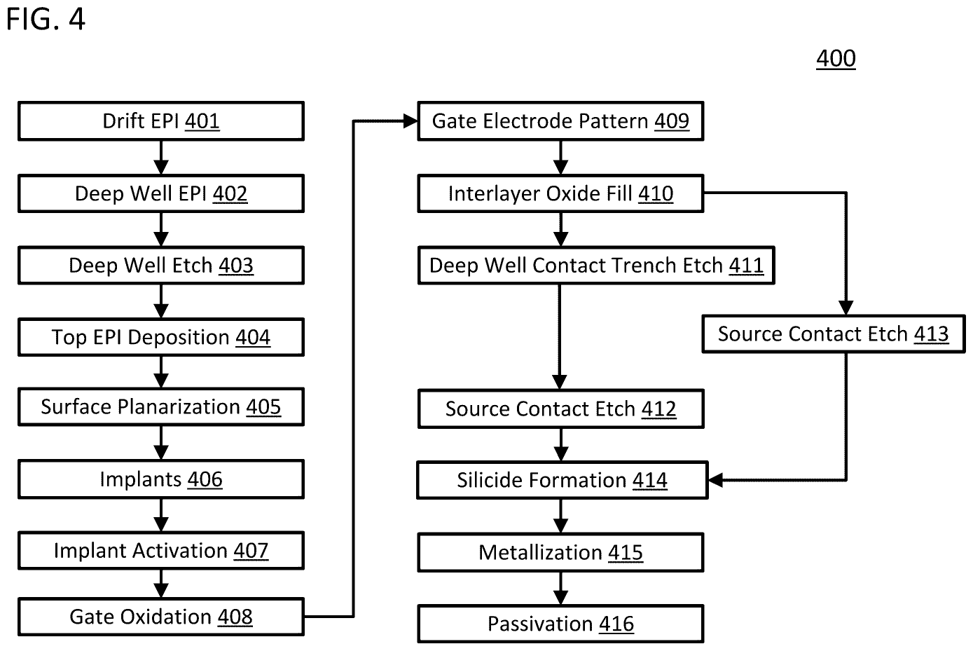

FIG. 4 illustrates a flow chart 400 for a set of methods for forming a SiC MISFET semiconductor device in accordance with specific embodiments of the inventions disclosed herein. Steps 401-405 of the process can be conducted to form various devices such as JBS diodes or JFETs in accordance with specific embodiments of the inventions disclosed herein. The disclosed methods can be used to form a MISFET device using the epitaxial formation of a heavily doped in situ deep well and the formation of a heavily doped trench contact. These steps can be used to form a MISFET such as device 200 in FIG. 2. Flow chart 400 also includes an alternative path through step 413 in which there is no formation of a heavily doped trench contact. This alternative path can be used to form a MISFET such as device 300 in FIG. 3. Step 413 includes the formation of a source contact mask and an etch prior to the formation of silicide region 303 for the contact between the source terminal and source contact SC.

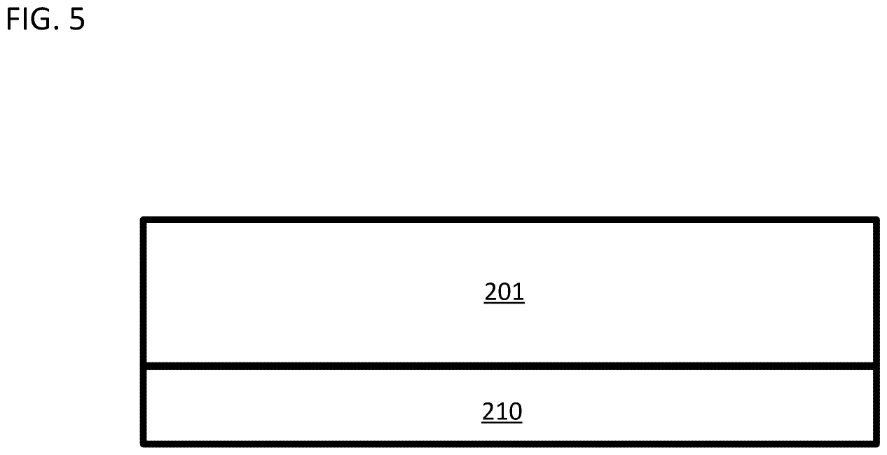

FIG. 5 shows the formation of a drift region 201 on substrate 210. The illustrated structure can be formed through the execution of step 401 which involves the epitaxial formation of a drift region 201 on a substrate 210.

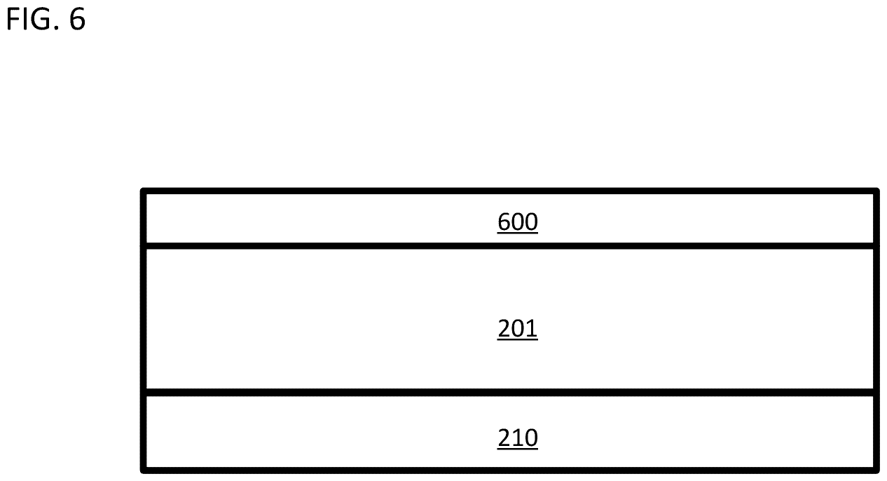

FIG. 6 shows the formation of an in situ doped deep well layer 600 on the drift region 201. The process can be conducted via the execution of step 402 which involves the epitaxial formation of an in situ doped semiconductor region on top of the drift region where the dopants are introduced to the layer as it is formed. The region can have the concentration for a deep well described above (e.g., peak greater than 5×10¹⁸ cm⁻³). In situ doped deep well layer 600 can be doped during epitaxial formation over the drift region 201. In specific embodiments in situ doped deep well layer 600 can have a peak doping concentration between 1×10¹⁹ to 1×10²¹.

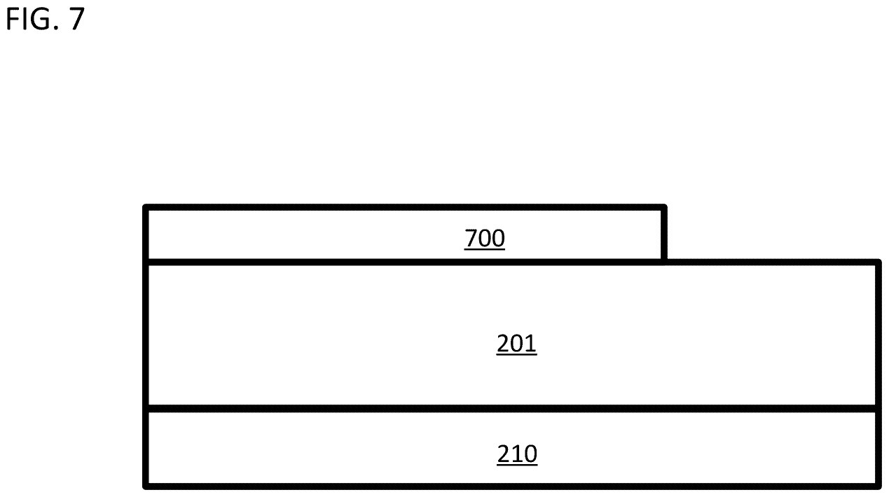

FIG. 7 shows the etching of the in situ doped region to form etched in situ doped semiconductor region 700. The process can be conducted via the execution of step 403 which involves the etching of the in situ doped region to form an etched in situ doped region. The etch can be conducted using a first mask. The etching can be selective to the difference in material of drift region 201 and in situ doped deep well layer 600 or it can be a timed etch. Regardless, the etch can be conducted to expose a surface of drift region 201.

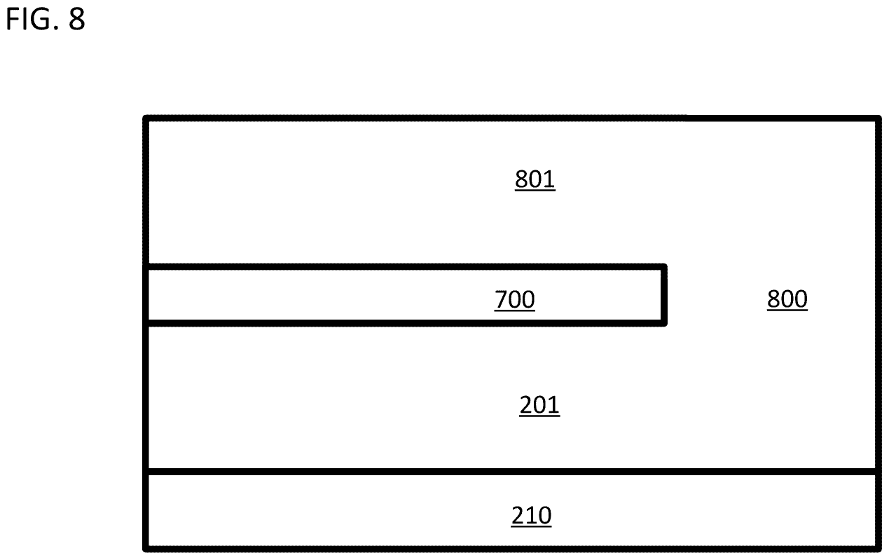

FIG. 8 shows how an epitaxial cap layer 801 can be grown from the exposed surface of drift region 201 over etched in situ doped semiconductor region 700. The process can be conducted via the execution of step 404 which involves forming a top epitaxial layer through the epitaxial growth of such a region and the execution of a step 405 to planarize the epitaxial layer for further processing. Epitaxial cap layer 801 can be a semiconductor region that has been grown by continuing the crystal structure of drift region 201. Now that epitaxial cap layer 801 has been formed, etched in situ doped semiconductor region 700 is no longer proximate the surface of the semiconductor wafer and it can serve as a deep well region. In specific embodiments, this deep well region can be between 0.5 and 3 microns below a structure formed on the new surface of the semiconductor wafer such as a gate of a MISFET transistor. For the avoidance of doubt, this depth refers to the distance between the top of the deep well region and the structure on the surface of the semiconductor wafer of the finalized device such as a gate of a MISFET transistor. In other words, a highest point of the first deep well region is between 0.5 and 3 microns below the gate. Additionally, this depth refers to the distance between what is referred to as the “first” deep well region herein with reference to embodiments that have both first and second deep well regions. As illustrated, epitaxial cap layer 801 can form part of JFET region 800 of the device. As will be seen, epitaxial cap layer 801 can also end up being used to form other portions of the device including a second deep well region. In contrast to some prior art approaches in which the deep well is formed by an implant through the higher layers of semiconductor material, the deep well region in this example (i.e., etched in situ doped semiconductor region 700) has been formed prior to the formation of the higher layers of semiconductor material (i.e., epitaxial cap layer 801). As such, the region formed by the epitaxial cap layer in the final device can be devoid of the implant damage that would otherwise occur in those regions due to deep well implants in prior art approaches.

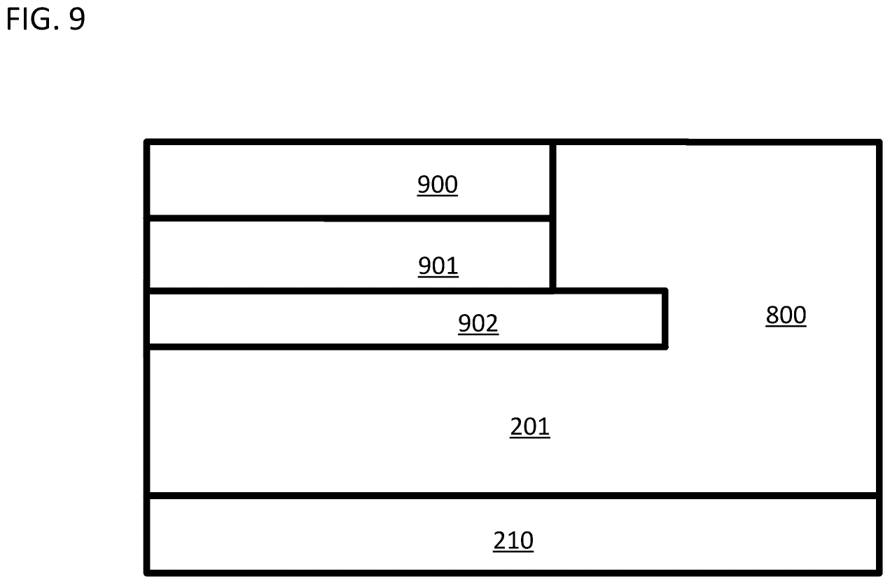

FIG. 9 shows the formation of a second deep well region 901 and a shallow well region 900 in the epitaxial cap layer. The etched in situ doped semiconductor region 700 is now labeled as first deep well region 902 to distinguish it from the second deep well region 901. However, both regions have the same conductivity type and both serve as a deep well for the finalized semiconductor device. Second deep well region 901 and shallow well region 900 can be formed by two sequenced masked implant steps conducted using the same mask. The process can be conducted via the execution of step 406 which involves implanting the top epitaxial layer with dopants to form second deep well region and shallow well region. The peak doping concentration of second deep well region 901 can be lower than that of the first deep well region 902. In specific embodiments, the second deep well region can have a peak doping concentration of between 1×10¹⁷ and 1×10¹⁹ cm⁻³. As a result, there may be less implant damage in the region of the epitaxially cap layer in which shallow well region 900 is formed than if they had the same doping concentration. However, in alternative approaches, a single region comprising second deep well region 901 and first deep well region 902 can have a substantially uniform dopant profile while still realizing some of the benefits disclosed herein. This is because the deeper portions of the deep well can be formed prior to the creation of the shallow well while the shallower portions of the deep well can be formed with an implant that, while aiming to create a heavy doping concentration, does not need to be as high energy given that the target area is shallower. As illustrated, the thickness and doping of second deep well region 901, are independent of the thickness and doping of first deep well region 902 as the thickness and doping are set by different processing steps. Also as illustrated, the interfaces of shallow well region 900 and second deep well region 901 with JFET region 800 are substantially aligned because both regions were formed using the same mask.

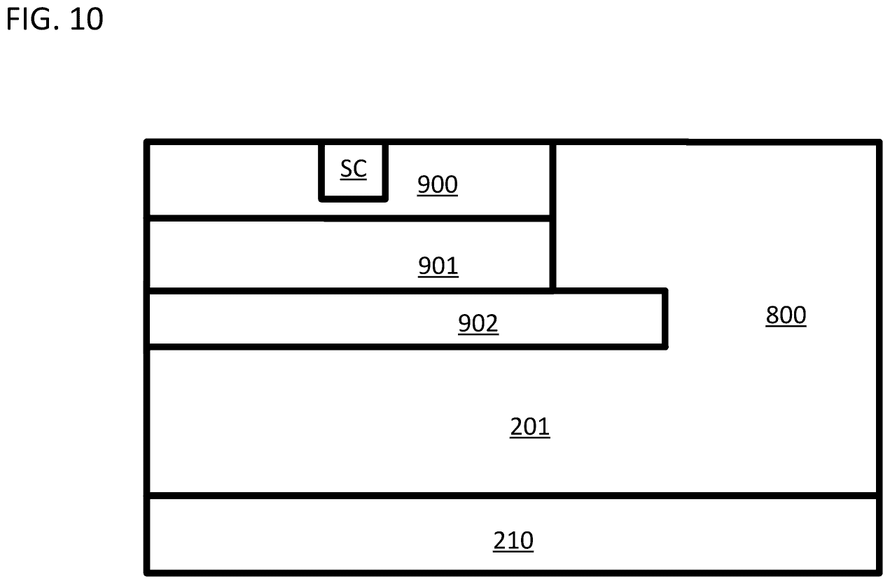

FIG. 10 shows the formation of source contact SC in shallow well region 900. The process can be conducted as part of the execution of step 406 which involves implanting the top epitaxial layer with dopants to form source contact SC. The source contact implant can be a high dose implant of a different conductivity type than shallow well region 900. The source contact implant can be conducted using another mask.

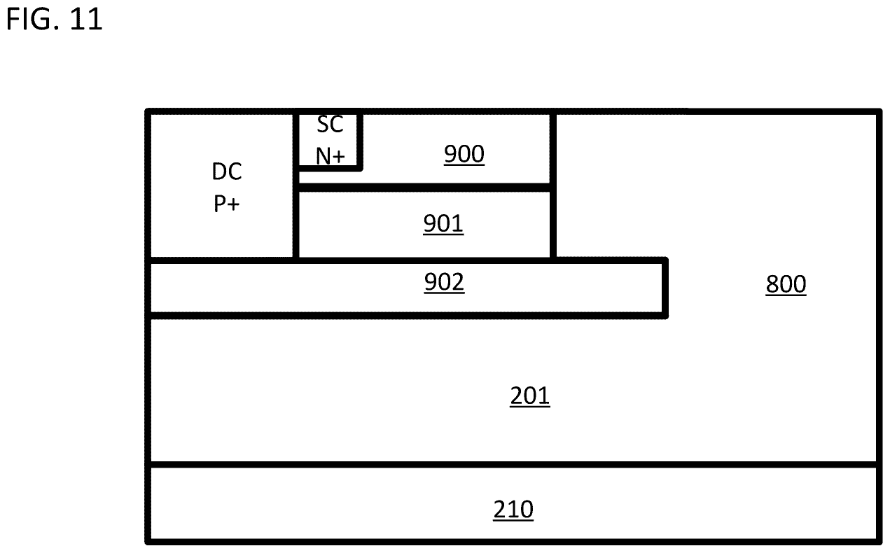

FIG. 11 shows the formation of a deep well contact DC in the surface of the device via a masked implant. The process can be conducted as part of the execution of step 406 which involves implanting the top epitaxial layer with dopants to form deep well contact DC. The deep well contact implant can be a high dose implant of the same conductivity type as the deep well region. As illustrated, the deep well contact region has been heavily doped with p-type dopants and the source contact region has been heavily doped with n-type dopants. The deep well contact implant can be conducted using another mask. The step can be followed by an implant activation step 407 such as a high temperature annealing step to activate the dopants introduced to the epitaxially cap layer via the formation of the second deep well region, the shallow well region, the source contact, and the deep well contact.

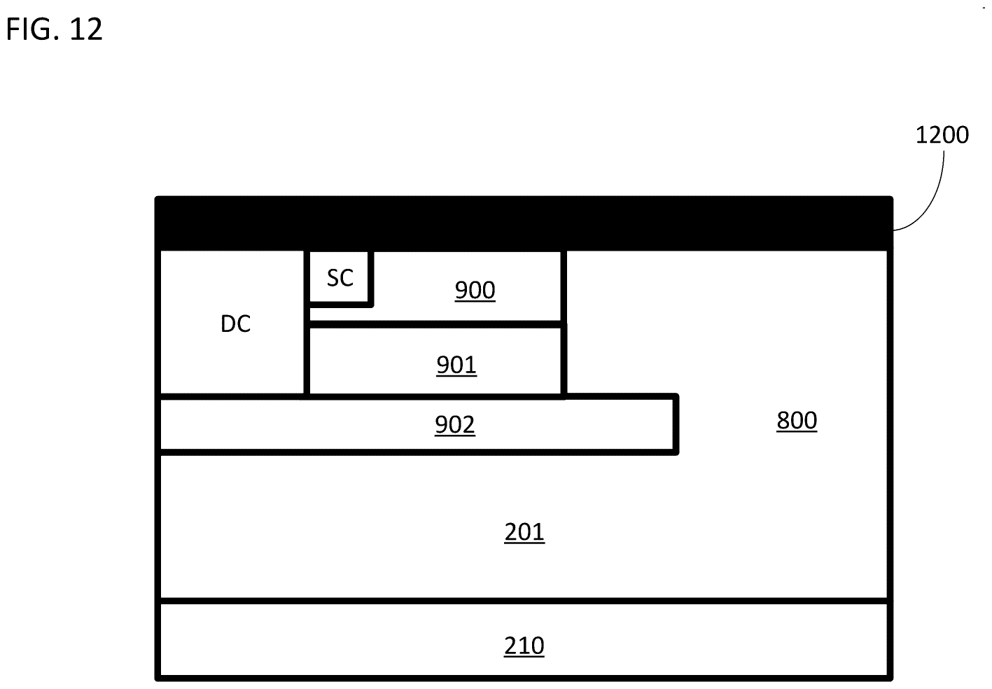

FIG. 12 continues this process flow with the formation of gate oxide 1200. Gate oxide 1200 can serve as the insulator for the finalized device. The process can be conducted as part of the execution of step 408 which involves forming a gate oxide on the surface of the semiconductor wafer. The illustrated step can be preceded by a field oxidation step to create the field oxide outside the periphery of the individual devices.

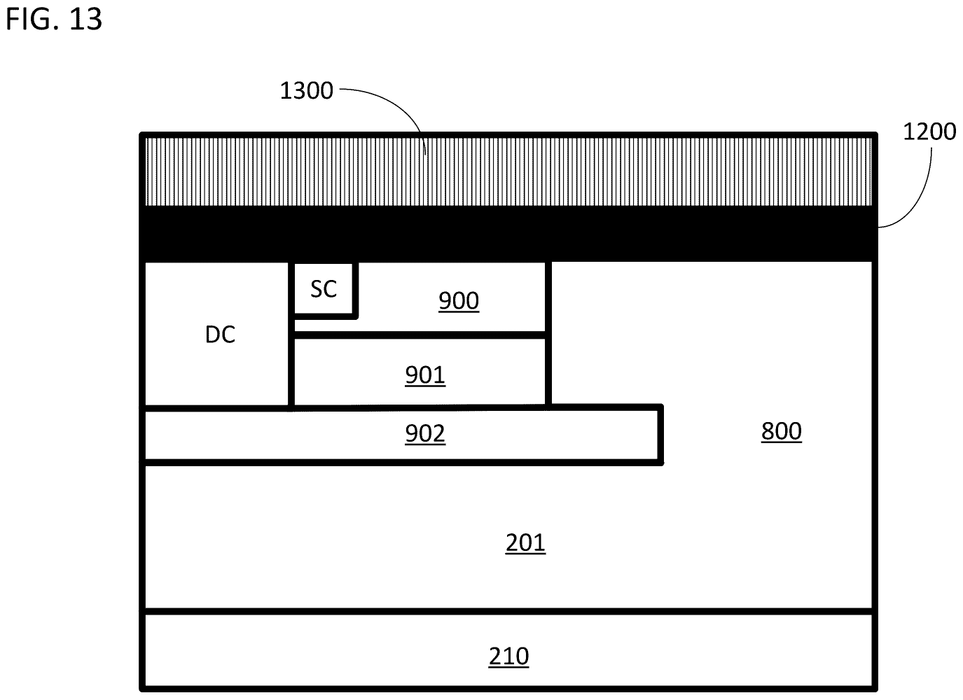

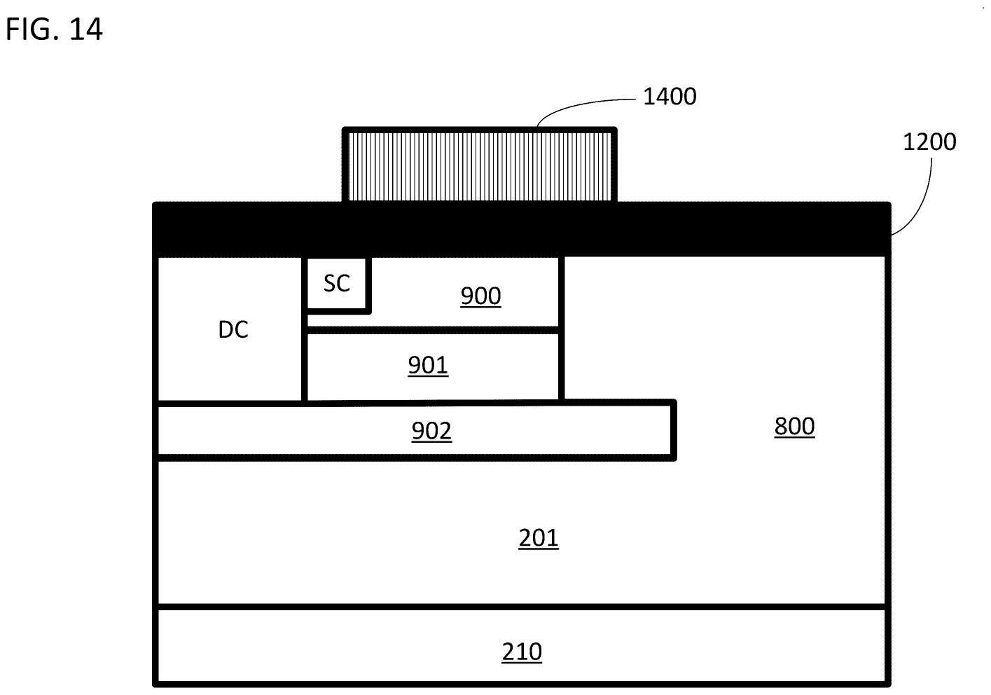

FIG. 13 continues this process flow with the formation of gate polysilicon layer 1300. The gate polysilicon can serve as the gate electrode for the finalized device. The process can be conducted as part of the execution of step 409 which involves forming gate polysilicon on the surface of the semiconductor wafer and then patterning the gate polysilicon using a masked etch to form the gate electrode. FIG. 14 accordingly continues this process flow with the formation of gate electrode 1400 by etching the gate polysilicon using another mask. The process can then continue with step 410 of forming an interlayer oxide fill to finalize the gate structure.

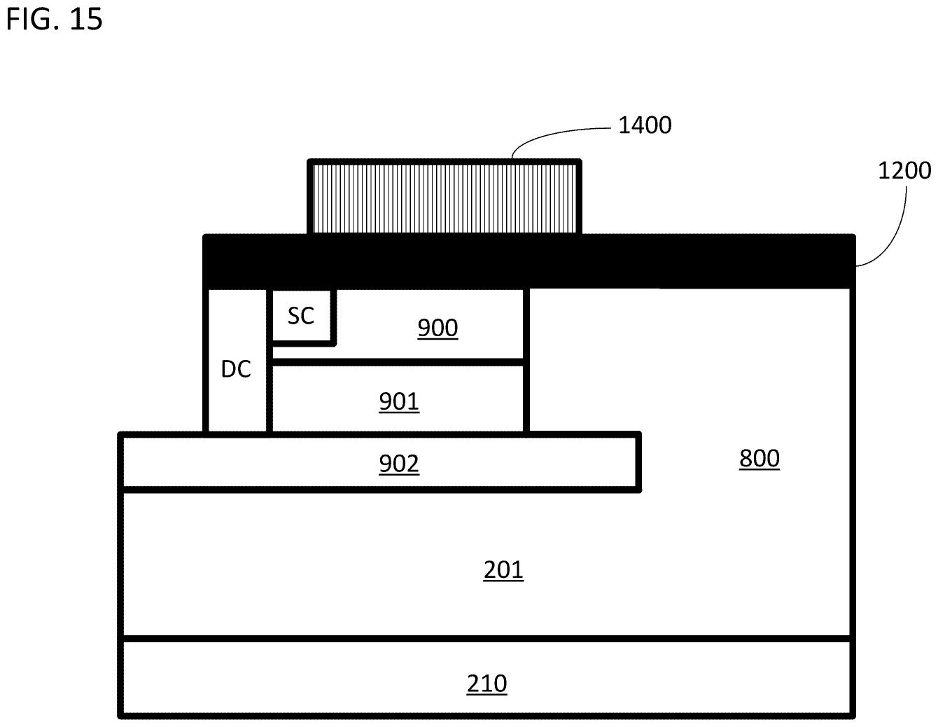

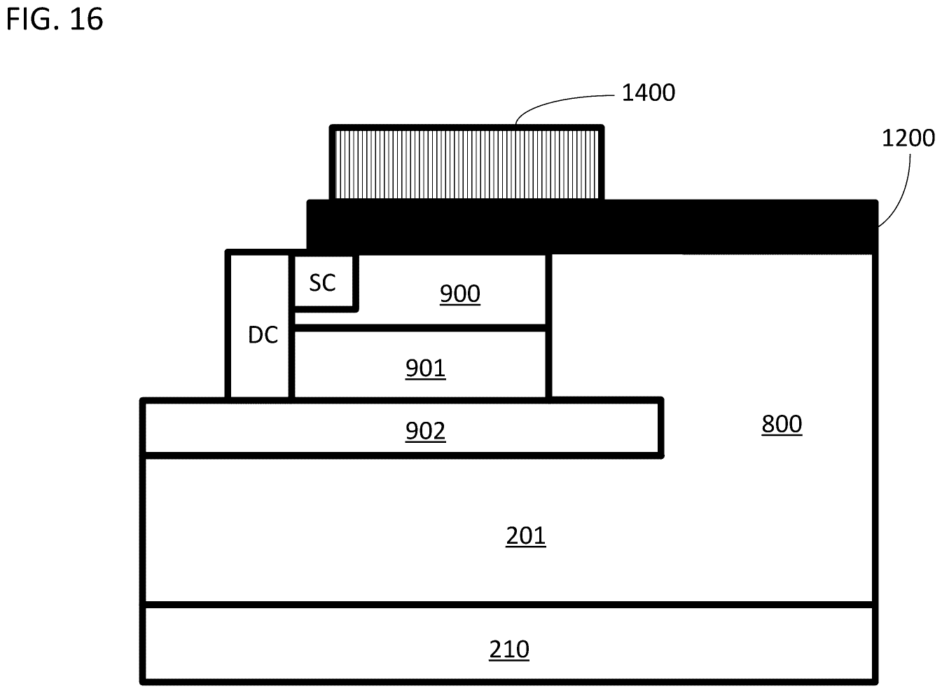

The process can then take an optional route through step 413 in which a trench is not formed in the semiconductor wafer to form a deep well contact or a step 411 in which such a trench is formed. These optional steps can lead to either device 200, in which a trench is formed, or device 300 in which a trench is not formed. The trench contact can lower the impedance and capacitance for the path used to bias the deep well which can result in improved performance in high radiation environments. FIG. 15 illustrates the execution of step 411 in that a trench has been formed by a masked etch that removes the gate insulator and a portion of the deep well contact. The etch can be a timed etch. FIG. 16 continues this process flow with another masked etch that exposes a top surface of the deep well contact DC and the source contact SC by removing the gate insulator. The etch can be selective for the gate insulator and semiconductor material. The process can be conducted through the execution of step 412 which exposes the source contact SC to make room for the source terminal of the device.

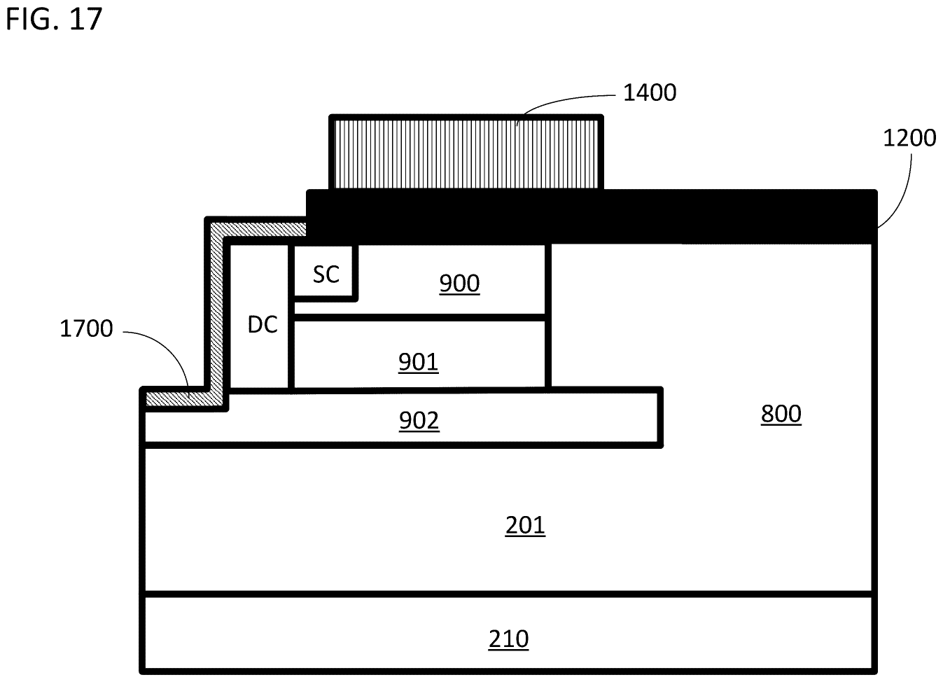

FIG. 17 illustrates the continuation of this process flow with the formation of a silicide 1700 over an exposed portion of the deep well, the deep well contact, and the source contact. In embodiments in which a trench was not formed, this step can involve forming silicide region 303 as in the cross section of device 300. Either process can be conducted through the execution of step 414 which involves the formation of a silicide for assuring electrical connectivity to the deep well contact DC and the source contact SC.

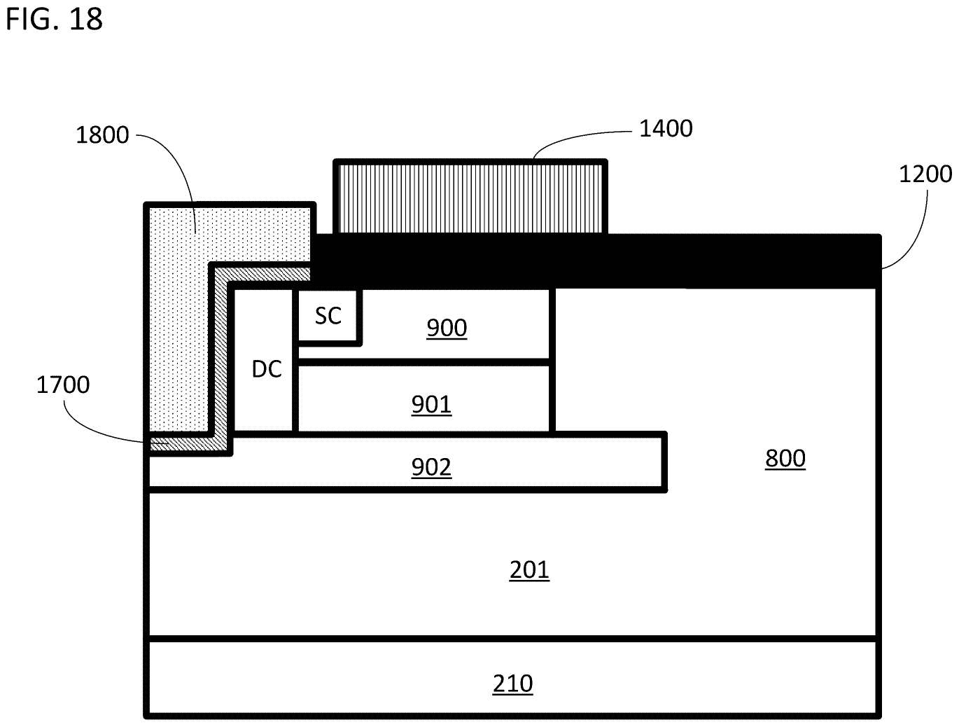

FIG. 18 illustrates the continuation of this process flow with the formation of a source terminal 1800 using a masked deposition of metal. This step can be conducted through the execution of step 415 which involves the metallization of the semiconductor device for the formation of top side contacts such as to the source or gate of the device. The masked deposition of metal can include a blanket deposition and a masked etch. Alternatively, the masked deposition can include the formation of a mask for the deposition. The process can conclude with the execution of step 416 in which a passivation layer is formed.

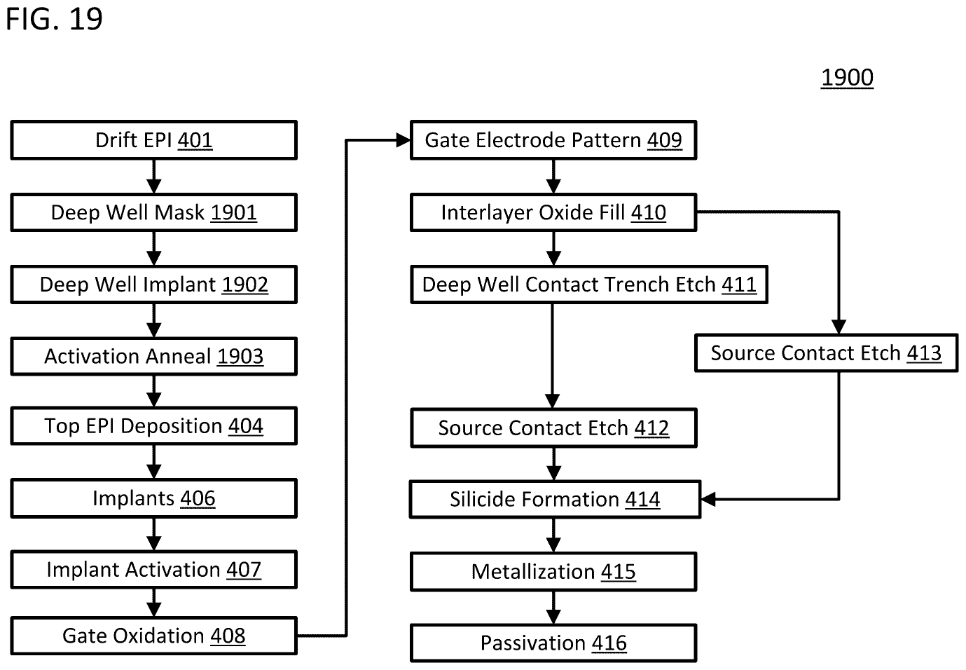

FIG. 19 illustrates a flow chart 1900 for a set of methods for forming a SiC MISFET semiconductor device using a masked implant and anneal to form the deep well region in accordance with specific embodiments of the inventions disclosed herein. The process includes forming a MISFET device using the epitaxial formation of a heavily doped in situ deep well formed on an etched surface and the formation of a heavily doped trench contact. Flow chart 1900 includes an alternative path through the flow chart for approaches in which there is no formation of a heavily doped trench contact. As illustrated, the alternative path includes the formation of a source contact mask and an etch prior to the formation of the silicide for the contact between the source terminal and the source contact in step 413.

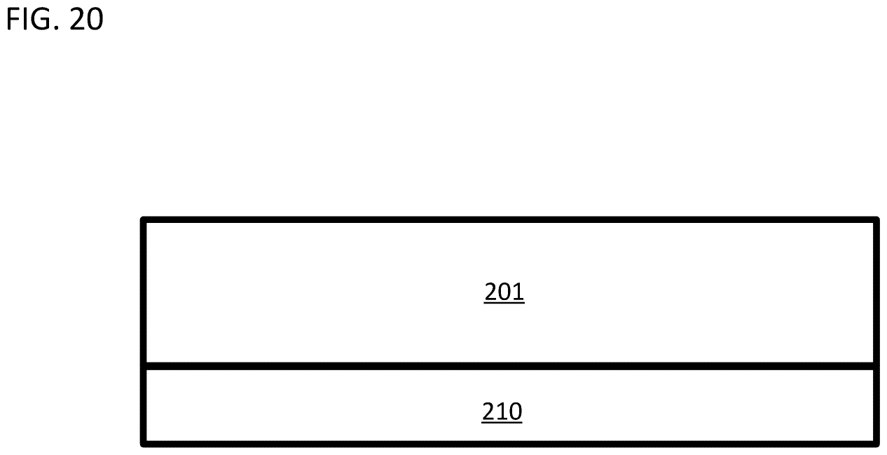

Methods that are in accordance with flow chart 1900 are similar to those of the methods in accordance with flow chart 400. However, the methods in accordance with flow chart 1900 form a deep well region on a drift layer using a masked implant and an activation anneal instead of the epitaxially formation of an in situ doped layer followed by an etch of the in situ doped layer as in the approaches in accordance with flow chart 400. An illustration of an example implementation of a method in accordance with flow chart 1900 with an emphasis on the steps that are not in common with flow chart 400 can be explained with reference to FIGS. 20-22.

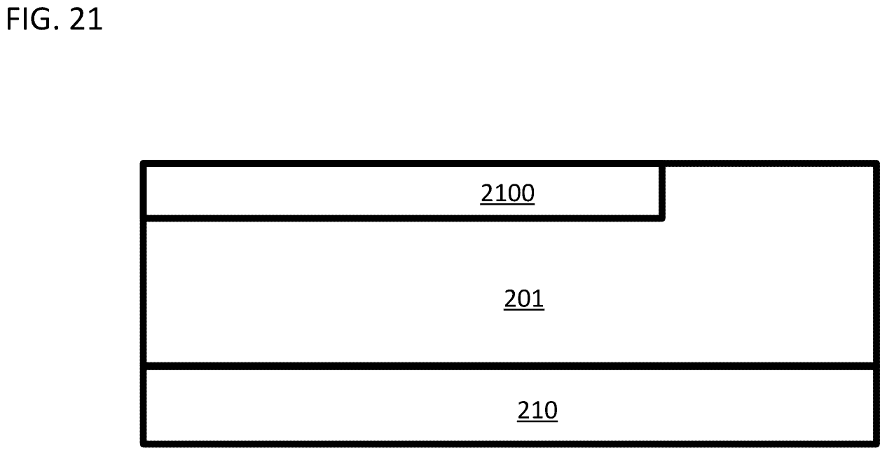

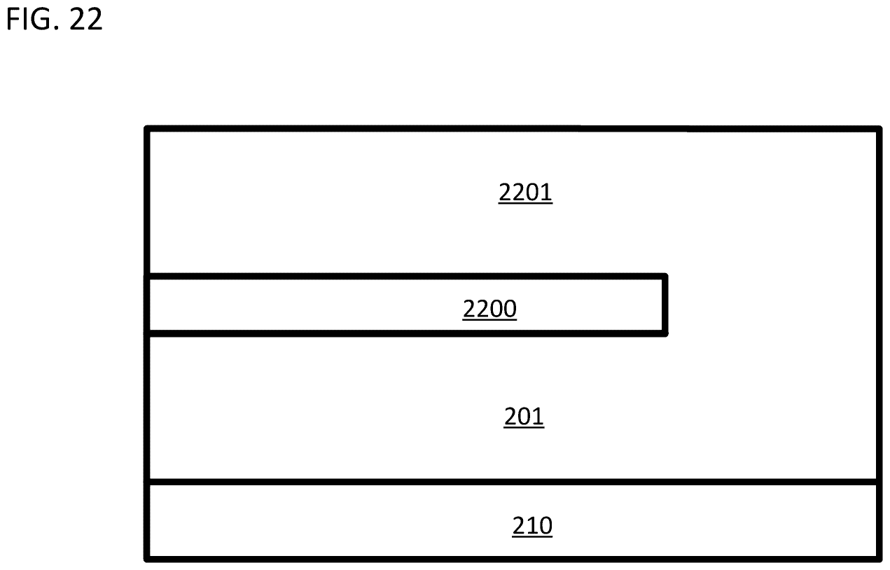

FIG. 20 shows the formation of a drift region 201 on a substrate 210. The step can be conducted using the epitaxial formation of drift region 201 on substrate 210. FIG. 21 shows the masked implant of drift region 201 to form an implanted region 2100. The step can be conducted by masking a portion of the drift region as in step 1901 and implanting the exposed portion as in step 1902. The implanted region 2100 can then be subjected to an annealing step as in step 1903 to activate the dopants and form a deep well region 2200 as shown in FIG. 22. Deep well region 2200 can have a high peak doping concentration (e.g., a peak doping concentration between 5×10¹⁸ cm⁻³ and 5×10²¹ cm⁻³). FIG. 22 shows how an epitaxial cap layer 2201 can be grown on top of the exposed surface of the drift region 201 and the deep well region 2200. Epitaxial cap layer 2201 can be a semiconductor region that has been grown by continuing the crystal structure of the drift region. As illustrated, this epitaxial cap layer can form part of the JFET region of the device. The process can then continue in the same fashion as illustrated above for FIGS. 9-18 to form a complete MISFET device with a trench contact. As can be seen in those figures, the epitaxial cap layer will also end up being used to form other portions of the device including a second deep well region. The process can alternatively continue as described above to form a complete MISFET device without a trench contact.

While the specification has been described in detail with respect to specific embodiments of the invention, it will be appreciated that those skilled in the art, upon attaining an understanding of the foregoing, may readily conceive of alterations to, variations of, and equivalents to these embodiments. For example, although the example of a vertical device was used throughout this disclosure, specific embodiments disclosed herein are more broadly applicable to lateral devices. As another example, while the disclosure focused on a single cell of a device, the approaches disclosed herein are applicable to devices with any number of such cells arrayed in multiple rows and columns. As another example, while devices having a first implant region with a first conductivity type being p-type were used as an example throughout this disclosure, the conductivity types of the various regions disclosed herein could be switched to form devices of opposite conductivity types. Furthermore, although silicon carbide and silicon semiconductor materials were provided by way of example, specific embodiments disclosed herein are broadly applicable to any form of semiconductor technology including any III-V semiconductor material and other compound semiconductor material. These and other modifications and variations to the present invention may be practiced by those skilled in the art, without departing from the scope of the present invention, which is more particularly set forth in the appended claims.

What is claimed is:

1. A process for forming a semiconductor device comprising:
forming, on a drift region having a first conductivity type, a deep well region for the semiconductor device, wherein the deep well region has a second conductivity type, and wherein the deep well region of the second conductivity type leaves a portion of a surface of the drift region exposed; and
epitaxially forming a semiconductor region that extends from the surface of the drift region to above the deep well region for the semiconductor device.

2. The process of claim 1, wherein the forming of the deep well region comprises:
epitaxially depositing a layer on the drift region; and
etching, using a mask, the layer to expose the portion of the surface of the drift region.

3. The process of claim 1, wherein the forming of the deep well region comprises:
implanting the drift region, using a mask, to form the deep well region.

4. The process of claim 1, wherein the deep well region is a first deep well region and the process further comprises:
forming a second deep well region in the semiconductor region; and
forming a shallow well region in the semiconductor region;
wherein: (i) the forming of the second deep well region comprises implanting the drift region using an implant; and (ii) the shallow well region of the semiconductor device does not include implant damage from the implant.

5. The process of claim 4, further comprising:
forming a source contact region in the shallow well region;
wherein the shallow well region includes a portion that is between the source contact region and the second deep well region.

6. The process of claim 1, further comprising:
forming a main current path region of the semiconductor device above the deep well region;
wherein: (i) the forming of the deep well region comprises implanting the semiconductor region using an implant; and (ii) the main current path region of the semiconductor device does not include implant damage from the implant.

7. The process of claim 1, wherein the deep well region is a first deep well region and the process further comprises:
implanting the semiconductor region, using a mask, to form a second deep well region for the semiconductor device.

8. The process of claim 7, wherein:
the forming of the first deep well region comprises implanting the drift region;
the first deep well region has a peak doping concentration between 10¹⁹ to 10²¹ impurity molecular entities per cubic centimeter; and
the second deep well region has a lower peak doping concentration than the first deep well region.

9. The process of claim 7, wherein:
the forming of the deep well region comprises epitaxially depositing a layer on the drift region, and etching, using a second mask, the layer to expose the portion of the surface of the drift region;
the first deep well region has a peak doping concentration between 10¹⁹ to 10²¹ impurity molecular entities per cubic centimeter; and
the second deep well region has a lower peak doping concentration than the first deep well region.

10. The process of claim 7, further comprising:
forming a gate for the semiconductor device;
wherein the first deep well region covers the gate from a bottom-up perspective.

11. The process of claim 7, further comprising:
forming a gate for the semiconductor device;
wherein: (i) the first deep well region has a lateral extent that is wider than the second deep well region; and (ii) the lateral extent is wider than a lateral extent of the gate.

12. The process of claim 11, wherein:
a highest point of the first deep well region is between 0.5 and 3 microns below the gate.

13. The process of claim 1, further comprising:
forming a trench from a top surface of the semiconductor region down to the deep well region; and
forming a contact to the deep well region in the trench.

14. A process for forming a vertical semiconductor device comprising:
forming, on a first semiconductor region having a first conductivity type, a first deep well region for the vertical semiconductor device using a first implant of a second conductivity type, wherein the first deep well region leaves a surface of the first semiconductor region exposed; and
epitaxially forming a second semiconductor region that extends from the surface of the first semiconductor region to above the first deep well region; and
wherein the first semiconductor region and the second semiconductor region form a main current path through the vertical semiconductor device from above the first deep well region to below the first deep well region.

15. The process of claim 14, further comprising:
implanting the second semiconductor region, using a mask, to form a second deep well region for the semiconductor device.

16. The process of claim 14, wherein the forming of the first deep well region comprises:
epitaxially depositing a layer on a drift region; and
etching, using a mask, the layer to expose a portion of the surface of the drift region.

17. A vertical device comprising:
a top side contact region of a first conductivity type;
a junction field effect region of the first conductivity type;
a shallow well region, of a second conductivity type; and
a deep well region, of the second conductivity type, below the shallow well region and having a peak doping concentration between 10¹⁹ to 10²¹ impurity molecular entities per cubic centimeter.

18. The vertical device of claim 17, wherein the deep well region is a first deep well region and further comprising:
a gate, wherein the first deep well region covers the gate from a bottom-up perspective; and
a second deep well region, wherein the first deep well region covers the second deep well region from a bottom-up perspective; and
wherein the first deep well region has a higher peak doping concentration than the second deep well region.

19. The vertical device of claim 18, wherein:
a highest point of the first deep well region is between 0.5 and 3 microns below the gate.

20. The vertical device of claim 18, wherein the vertical device is a vertical transistor and further comprises:
a channel of the vertical transistor formed in the shallow well region;
wherein the deep well region is formed by an implant and the shallow well region does not include implant damage from the implant.

21. The vertical device of claim 18, wherein:
the top side contact region is a source contact region;
the shallow well region separates the second deep well region and the source contact region; and
a transistor channel is formed in the shallow well region.

22. The vertical device of claim 17, further comprising:
a deep well contact region extending from a top surface of a semiconductor region down to the deep well region.

23. The vertical device of claim 22, wherein the deep well contact region comprises:
a trench formed in the semiconductor region; and
a layer of silicide in the trench and in contact with the deep well region.
